(19) United States
(12) Patent Application Publication
(10) Pub. No.: US 2006/0040135 A1
(43) Pub. Date: Feb. 23, 2006

(54) Electroluminescent device and method of fabricating the same, and electronic apparatus

(75) Inventor: Katsuyuki Morii, Lausanne (CH)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/197,323

(22) Filed: Aug. 5, 2005

(30) Foreign Application Priority Data
Aug. 20, 2004 (JP) 2004-240450

(51) Int. Cl. H05B 33/12

(52) U.S. Cl. 428/690; 313/503; 428/917; 428/212; 428/328; 313/504; 313/506; 427/66

(57) ABSTRACT

An aspect of the invention provides an electroluminescent device including an emissive section, an electron injection and transport section, and a hole injection and transfer section between electrodes, wherein the electron injection and transport section is made from an inorganic semiconductor material, the hole injection and transfer section from an organic semiconductor material, and the emissive section from a metallic complex.

### BACKGROUND

The present invention relates to an electroluminescent device fabricated by using a liquid phase process and a method of fabricating such an electroluminescent device, and an electronic apparatus.

In general, an organic electroluminescent element constituting an organic electroluminescent device contains an organic emissive layer made from an organic light emitting material between the anode and the cathode, wherein electrons and holes injected from both electrodes recombine in the emissive layer and excited energy is emitted as light. The organic electroluminescent device has a large charge injection barrier between each electrode and the emissive layer, and therefore typically has a multilayered structure containing a hole injection layer (also referred to as a hole transfer layer) acting as an anode buffer layer and an electron injection layer (also referred to as an electron transport layer) acting as a cathode buffer layer.

Among constituents of the organic electroluminescent device, an electron injection material (also referred to as an electron transport material) particularly has high reactivity with oxygen, etc., in principle, that is, a high possibility of producing a chemical change under normal conditions, and therefore it is difficult to maintain the reliability for long periods. Thus, portions that serve to inject and transport electrons, including the cathode, are one of factors in degradation of the device. On the other hand, demand for organic electroluminescence is increasing day by day. The reliability is becoming a significant challenge above all. An electron injection transport layer using an organic material, which conventionally exists, is not sufficient to satisfy the demand, and therefore it is expected to create a novel element structure including a hole injection transport part and a light-emitting part. In addition, the difficulty of controlling gradation in the low brightness region is noted as a problem regarding the display of the current structure. This fundamentally arises from the current element structure having and utilizing an interface parallel to an electrode.

Examples of related art structures are disclosed in Japanese Unexamined Patent Publication Nos. Hei 10-12377, 2000-252076, and 2000-252079. Further, related art examples are also disclosed in Appl. Phys. Lett., 51, 1997, p. 34; Appl. Phys. Lett., 71, 1997, p. 34; and Nature 357, 1992, p. 477.

### SUMMARY

An advantage of the invention is to provide a highly reliable electroluminescent element at low energy.

Another advantage of the invention is to provide an electroluminescent element with improved gradation control in the low brightness region.

A further advantage of the invention is to provide an electronic apparatus containing an electroluminescent device according to an aspect of the invention.

According to an aspect of the invention, an electroluminescent device includes an emissive section, an electron injection and transport section, and a hole injection and transfer section between electrodes; wherein the electron injection and transport section is made from an inorganic semiconductor material, the hole injection and transfer section from an organic semiconductor material, and the emissive section from a metallic complex.

In the electroluminescent device according to an aspect of the invention, at least one of interfaces between a plurality of the functional sections may be formed by phase separation.

The phase separation interfaces may be substantially parallel to the electrode. It is further preferable that the inorganic semiconductor material is a particulate.

Preferably, the inorganic semiconductor material includes at least two types having different chemical compositions, and is arranged so that energy of a conductive band is higher as the inorganic semiconductor material is closer to a cathode.

Further in the electroluminescent device according to an aspect of the invention, at least one type of the inorganic semiconductor particulate may be covered with an organic substance having fluoroalkyle, and the inorganic semiconductor particulate covered may be in contact with a cathode.

In the particulate, a plurality of types of inorganic semiconductor materials may be included in one particulate. Further, the inorganic semiconductor material is preferably a metallic oxide.

In the electroluminescent device according to an aspect of the invention, the inorganic semiconductor particulate preferably has a diameter equal to or less than 10 nm. Further, at least one type of the particulate of the inorganic semiconductor material is preferably provided with a metallic complex by a covalent bond.

Also, one of the metallic oxides may be a zirconium oxide; central metal of the metallic complex may be iridium.

In the electroluminescent device according to an aspect of the invention, it is preferable that the organic semiconductor material is a hole-transferring polymer. Further, a plurality of the organic semiconductor materials may be mixed, each having a phase separation interface, and the organic semiconductor material may have a triphenylamine skeleton. The inorganic semiconductor is utilized for electron injection and propagation, which might be important factors in degradation. Emission of light is accomplished by utilizing a metallic compound that possesses a high resistance to oxidation-reduction. Fabrication by low energy as well as interface control are attained in an aspect of the invention by using particulates for an inorganic semiconductor and covering them with an organic polymer that is excellent for forming a film. This organic polymer serves to support the injection and propagation of holes and the electron conduction in the inorganic semiconductor.

An advantage of the electroluminescent device according to an aspect of the invention is gradation control in the low brightness region. The electroluminescent device does not have an interface parallel to the electrode but includes an interface substantially parallel to the electrode that is constituted of a phase separation interface generated by a liquid phase process. This structure is considered to be preferable in terms of reliability because many luminous points are utilized.

In a method of fabricating the electroluminescent device according to an aspect of the invention, films of all layers except for the electrode are formed by a liquid phase process. The use of the liquid phase process enables the light-emitting functional part to be formed in a simple manner in comparison with the use of a gas phase process. The liquid phase process may be a spin-coating method, a dip method, or a droplet discharging method.

The method of fabricating the electroluminescent device according to an aspect of the invention controls a phase separation structure by controlling an atmosphere in a vicinity of a gas-liquid interface when forming a film.

The method of fabricating the electroluminescent device according to an aspect of the invention uses a solution having all the particulates of the organic material, the metallic complex, and the metallic compound mixed in the liquid phase process.

An electronic apparatus according to an aspect of the invention includes the electroluminescent device according to an aspect of the invention.

### BRIEF DESCRIPTION OF THE DRAWINGS

The invention will be described with reference to the accompanying drawings, wherein like numbers refer to like elements, and wherein:

FIG. 1 is a plan view schematically showing the structure of an electroluminescent device of an embodiment of the invention;

FIG. 2 is an enlarged sectional view of a main part taken along the line A-A in FIG. 1;

FIGS. 3A to 3C are sections for illustrating a fabrication method of an electroluminescent device in the order of steps;

FIGS. 4A and 4B are sectional views for illustrating steps subsequent to the step shown in FIG. 3C

FIG. 5 is a schematic view representing an embodiment of the invention; and

FIG. 6 is a perspective view showing an electronic apparatus of an embodiment of the invention.

### DETAILED DESCRIPTION OF EMBODIMENTS

An exemplary embodiment of the invention will now be described.

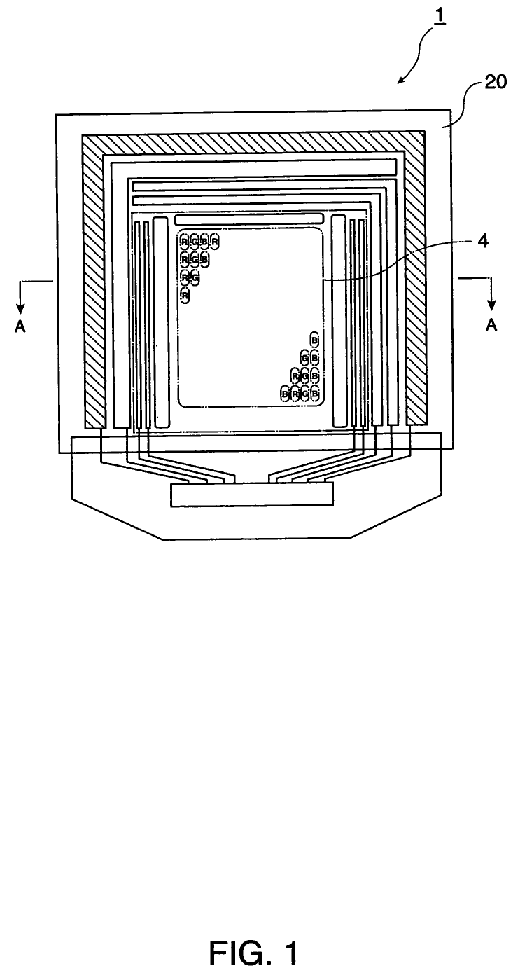

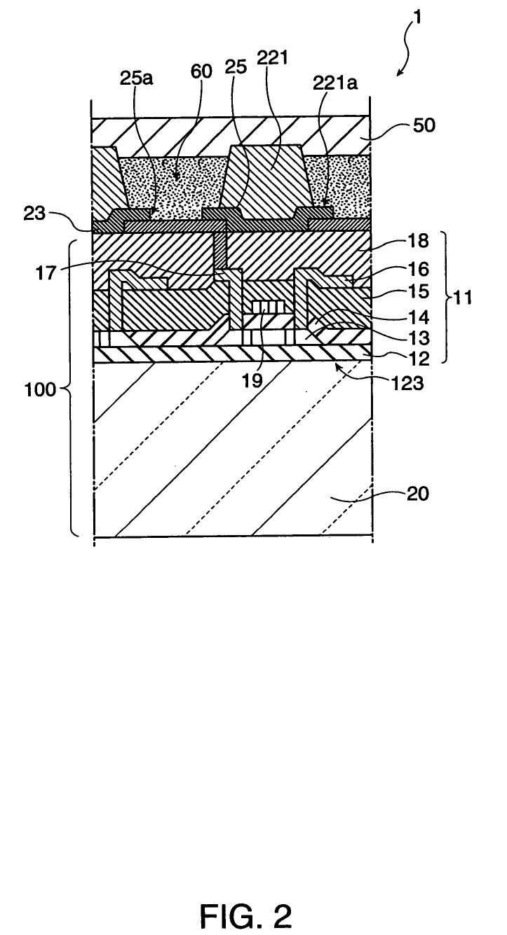

An example of the electroluminescent device according to the present embodiment will be described with reference to FIGS. 1 and 2. FIG. 1 is a plan view schematically showing the structure of an electroluminescent device 1; FIG. 2 is a sectional view schematically showing the sectional structure taken along the line A-A in FIG. 1.

The electroluminescent device 1 contains dots that emit green light (G) in an actual display region 4, as shown in FIG. 1, thereby enabling a monochromatic display. In the embodiment, green in monochrome is displayed, but the selection of a ligand in a complex makes it possible to display other colors and further to display the full range of colors.

The electroluminescent device 1 of the embodiment has a structure of bottom emission type, as shown in FIG. 2. In such a structure, light is taken from the side of a substrate 20, and therefore a transparent or translucent substrate is employed as the substrate 20; for example, glass, quartz, resin (plastic, plastic films) or the like is used.

If the electroluminescent device is of the so-called top emission type, the device has a structure in which light is taken from the side of a sealing substrate (not shown) on the opposite side to the substrate 20. Accordingly, either a transparent substrate or a translucent substrate can be used as the substrate 20. Examples of the translucent substrate include substrates formed by application of insulating such as surface oxidization to ceramics made from aluminum oxide, etc., and metal sheets formed of stainless steel, etc., or substrates of thermosetting resin, thermoplastic resin, etc.

In the embodiment, an electroluminescent element is disposed on a base body 100. The base body 100 includes the substrate 20 and a circuit section 11 formed on the substrate 20.

The circuit section 11 includes a protective layer 12 constituted of, for example, a silicon oxide layer formed on the substrate 20, a TFT for driving 123 formed on a protective layer, a first interlayer insulating layer 15, and a second interlayer insulating layer 18. The TFT for driving 123 includes a semiconductor layer 13 made from silicon, a gate insulating layer 14 formed on the semiconductor layer 13, a gate electrode 19 formed on the gate insulating layer 14, a source electrode 16, and a drain electrode 17.

An electroluminescent element is disposed on the circuit section 11. The electroluminescent element contains a pixel electrode 23 that functions as an anode, a light-emitting functional layer 60 formed on the pixel electrode 23, and a cathode 50 formed on the light-emitting functional layer 60.

In the electroluminescent element having such a structure, holes injected from the pixel electrode 23 functioning as the anode and electrons from the cathode 50 combine to emit light in the light-emitting functional layer 60.

The pixel electrode 23 functioning as the anode is made from a transparent conductive material, because the electroluminescent device is of a bottom emission type in the embodiment. As the transparent conductive material, indium tin oxide (ITO) can be used, and in addition, indium oxide-zinc oxide amorphous material (Indium Zinc Oxide: IZO (registered trade mark)) (made by Idemitsu Kosan Co. Ltd.), for example, can be used.

The film thickness of the pixel electrode 23 is not particularly restricted and therefore may be 50 to 200 nm, for example. By applying an oxygen plasma treatment to the surface of the pixel electrode 23, the lyophilicity is imparted to the surface while the surface is cleaned and the work function is adjusted. As conditions of the oxygen plasma treatment, plasma power is 100 to 800 kW, an oxygen gas flow volume is 50 to 100 ml/min, a substrate transportation velocity is 0.5 to 10 mm/sec, and a substrate temperature is 70 to 90 degree Celsius.

It is possible to use as the light-emitting material from which the light-emitting functional part 60 is made triarylamine-based polymer (for example, ADS254BE made by ADS shown below as Compound 1), polyvinyl carbazole shown below as Compound 2, and the like in organic substances; 3-coordinate iridium-containing metallic complex having 2,2′-bipyridinyl-4,4′-dicarboxylic acid, shown as Compound 3, as a ligand and the like in metallic complexes; zirconium oxide, titanium oxide, silicon carbide, zinc oxide, zinc sulfide, cadmium selenide, niobium oxide, tin oxide, and the like in particulates of metallic compounds; and in addition, a mixture of tin and zinc oxide and the like.

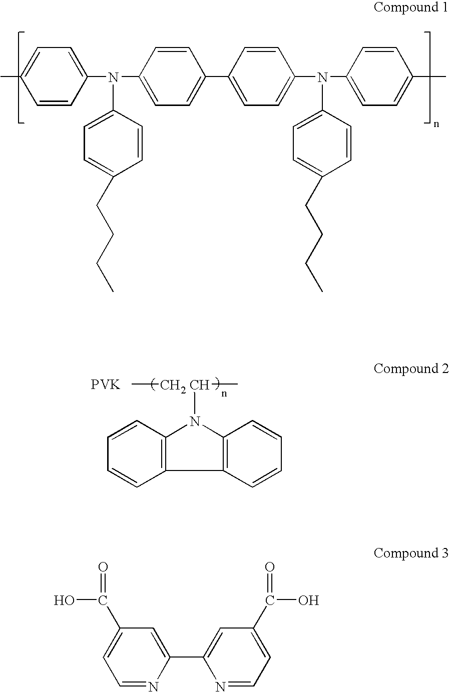

The cathode 50 is formed to cover the light-emitting functional part 60 and an organic bank layer 221.

As the material for forming the cathode 50, a material with small work function, such as calcium and magnesium, can be used for the portion on the side of the light-emitting functional part 60 (lower side). A material with work function larger than that of the portion on the side of the light-emitting functional part 60, such as aluminum, can be used for the portion on the upper side (sealing side). In an embodiment of the invention, however, the cathode may consist of only the portion on the upper side (sealing side), depending on the manner of selecting the light-emitting functional layer. This aluminum can also function as a reflection layer that reflects the emitted light from the light-emitting functional part 60. The film thickness of the electrode 50 is not particularly restricted; it may be, for example, 100 to 1000 nm, and more preferably 200 to 500 nm. In addition, the electroluminescent device in the embodiment is of a bottom emission type, and therefore it is not necessary that the electrode 50 is particularly light transmissive.

The surface of the second interlayer insulating layer 18 on which the pixel electrode 23 is formed is covered with the pixel electrode 23, a lyophilicity control layer 25 mainly made from a lyophilic material such as silicon oxide, and the organic bank layer 221 made from acrylate resin or polyimide. On the pixel electrode 23, a hole injection layer 70 and the light-emitting functional part 60 are deposited in this order from the side of the pixel electrode 23 in the insides of an opening 25a provided in the lyophilicity control layer 25 and an opening 221a provided in the organic bank layer 221. Incidentally, the term “lyophilicity” of the lyophilicity control layer 25 in the embodiment means being more lyophilic than at least a material such as acrylate resin or polyimide from which the organic bank layer 221 is made.

### EXAMPLE

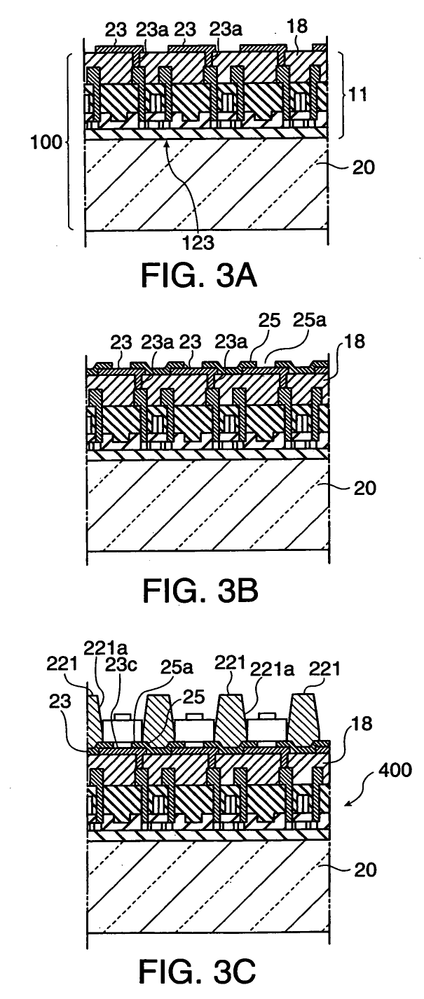

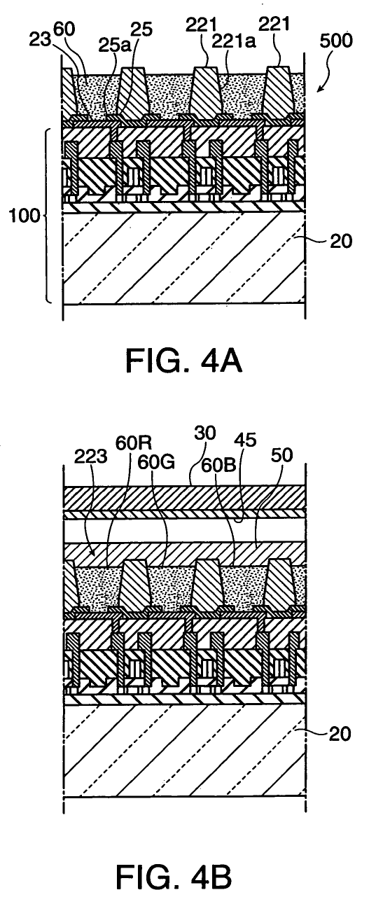

An example of fabrication method of the electroluminescent device 1 according to the embodiment will next be described with reference to FIGS. 3A through 3C and FIGS. 4A and 4B. The sectional views shown in FIGS. 3A through 3C and FIGS. 4A and 4B are drawings corresponding to the portions of sectional views taken along the line A-A in FIG. 1.

(1) As shown in FIG. 3A, the portion reaching the circuit section 11 shown in FIG. 2 is formed on the surface of the substrate 20 by the known art such that the base body 100 is obtained, as shown in FIG. 3A. Subsequently, a transparent conductive layer, which will be the pixel electrode 23, is formed to cover the entire surface of the top layer (the second interlayer insulating layer 18) of the base body 100. The pixel electrode 23 is then formed by patterning this transparent conductive layer.

(2) As shown in FIG. 3B, the lyophilicity control layer 25 constituted of an insulating layer is formed on the pixel electrode 23 and second interlayer insulating layer 18. Subsequently, in the lyophilicity control layer 25, a black matrix layer (not shown) is formed in the concave portion that is formed to be located between two different pixel electrodes 23. The black matrix layer can be formed, in particular, in the concave portion of the lyophilicity control layer 25 by a sputtering method, for example, with the use of chromium metal.

(3) As shown in FIG. 3C, the organic bank layer 221 is formed at a prescribed location of the lyophilicity control layer 25, and specifically at a location to cover the black matrix layer. The method for forming the organic bank layer is that a resist such as acrylate resin or polyimide dissolved in a solvent is applied by various types of coating methods such as a spin coating method and a dip coating method so that an organic matter layer is formed. The constituent material of the organic matter layer may be any one that is not dissolved in the solvent made of the liquid material described later and is easy to pattern by etching or the like. Subsequently, the organic matter layer is patterned by using a photolithography technique and an etching technique to form the opening 221a, thereby forming the organic bank layer 221.

A region exhibiting lyophilicity and a region exhibiting lyophobicity are formed by a plasma treatment. Specifically, the plasma treatment includes a preheating step, a step of making the top surface of the organic bank layer 221, a wall surface of the opening 221a, an electrode surface 23c of the pixel electrode 23, and the top surface of the lyophilicity control layer 25 lyophilic, a step of making the top surface of the organic bank layer 221 and a wall surface of the opening 221a lyophobic, and a cooling step.

A target object of the treatment (a layered body having the pixel electrode 23, the organic bank layer 221 and others deposited on the base body 100) is heated at a predetermined temperature such as 70 to 80 degree Celsius and then a plasma treatment in the air atmosphere using oxygen as reaction gas (an oxygen plasma treatment) is performed as the step of making surfaces lyophilic. As the step of making surfaces lyophobic, a plasma treatment in the air atmosphere using tetrafluoromethane as a reaction gas (CF₄ plasma treatment) is performed, and the target object heated by the plasma treatment is then cooled to room temperature. As a result, lyophilicity and lyophobicity can be imparted to predetermined positions.

In the CF₄ plasma treatment, the electrode surface 23c of the pixel electrode 23 and the lyophilicity control layer 25 are affected more or less, but ITO, which is a material of the pixel electrode 23, and silicon oxide and titanium oxide, etc., which are constituent materials of the lyophilicity control layer 25, have low affinities for fluorine, and therefore the hydroxyl group imparted in the step of making the surfaces lyophilic is never replaced with the fluorine group, maintaining the lyophilicity of the pixel electrode 23 and the lyophilicity control layer 25.

(4) As shown in FIG. 4A, the light-emitting functional part 60 is formed. In the step of forming the light-emitting functional part 60, a liquid phase process is performed. The term “liquid phase process” means a method of dissolving and dispersing a material to be used for film formation to a liquid state and then fabricating a thin film using the material in a liquid state by a spin-coating method, a dip method, a droplet discharging method (an ink-jet method), or the like. The spin-coating method and dip method are suitable for coating the entire surface, whereas the droplet discharging method can pattern a thin film at a desired location. Such a liquid phase process is the same as used in the film formation step for the cathode and the like described later.

In the step of forming the light-emitting functional layer, the light-emitting functional layer 60 can be formed at a predetermined location by applying a mixture of inorganic semiconductor particulates, a metallic compound, and an organic substance from which the light-emitting functional layer is made onto the electrode surface 23c without a need for patterning, for example, by etching.

If a material for forming the light-emitting functional layer is selectively applied by a droplet discharging method (an ink-jet method), the method fills a droplet discharge head (not shown) with the material for forming the light-emitting functional layer, lets a discharge nozzle of the droplet discharge head face the electrode surface 23c located in the opening 25a formed in the lyophilicity control layer 25, and discharges a droplet for which a liquid amount per droplet is controlled to the electrode surface 23c while relatively moving the droplet discharge head and a base.

The droplet discharged from the discharge nozzle spreads on the electrode surface 23c to which the treatment for lyophilicity was applied such that opening 25a of the lyophilicity control layer 25 is filled with the droplet. On the other hand, the top surface of the organic bank layer 221 to which the treatment for lyophobicity was applied repels the droplet, and therefore the droplet does not adhere onto it. Accordingly, even if the droplet is discharged onto the top surface of the organic bank layer 221 away from a predetermined discharging location, the top surface never gets wet by the droplet and bouncing droplet rolls into the opening 25a of the lyophilicity control layer 25. Thus, the droplet is readily and accurately provided at a predetermined location.

The light-emitting materials from which the light-emitting functional part 60 is made, including ones described above, may include polyvinyl carbazole, polyfluorene-based polymer derivatives, (poly)paraphenylenevinylene derivatives, polyphenylene derivatives, polythiophene derivatives, triarylamine derivatives, and the like as organic substances; a 3-coordinate iridium-containing metallic complex having 2,2′-bipyridinyl-4,4′-dicarboxylic acid as a ligand and the like as metallic complexes; zirconium oxide, titanium silicon oxide carbide, zinc oxide, zinc sulfide, cadmium selenide, niobium oxide, tin oxide, and the like as particulates of the metallic compound; and in addition, a mixture of tin and zinc oxide and the like.

An embodiment of the light-emitting functional part in this preferred embodiment will now be described.

Synthesis of a complex will be described. 2,2′-bipyridinyl-4,4′-dicarboxylic acid (made by Tokyo Kaseikogyo Co., Ltd.) described above is dissolved in a mixed solvent of water and 2-ethoxyethanol and the like. Separately, iridium chloride is dissolved in a similar solvent. The dissolution concentration should be adjusted so that the ratio of ligands, which are excessive, to metal is 5 to 1. After the reflux is performed for one or two days, a precipitate is taken out using a glass filter. The precipitate is then cleaned with ethanol and dried. At this point, an iridium complex is completed. In order to place this complex on a zirconium oxide, after the complex is dissolved in a halogen-based solvent (chloroform in this case), the dissolved complex is suitably added to the zirconium oxide in a state of being dispersed by a fluxing material that separately includes the same type of solvent. After the addition is completed, the solvent continues to be stirred for one day in order to cause a sufficient reaction. Thereby, zirconium oxide particulates covered with the iridium complex is completed. ADS254BE and F8, shown as Compound 4, that is polyfluorene-based polymer is dissolved in a nonpolar solvent such as xylene, toluene, cyclohexylbenzene, or dihydrobenzofuran, and the zirconium oxide processed as described above is added to the obtained solution. After the zirconium oxide is well dispersed in the solution, the solution is applied to the anode 23, for example ITO, by a liquid phase process. The liquid phase process, as the term is used at this point, means a method for fabricating a thin film by a spin-coating method, a dip method, a droplet discharging method (an ink-jet method), or the like, as same as described above. During the film formation, the atmosphere in the vicinity of the gas-liquid interface is controlled. In this case, the vicinity is filled with polar solvent vapor so as to collect many inorganic semiconductor particulates onto the film surface. Examples of the polar solvent vapor include water, alcohol, and the like; isopropyl alcohol was used in this case. A portion of the light-emitting functional part is thus completed. An inorganic semiconductor particulate layer is further created thereon.

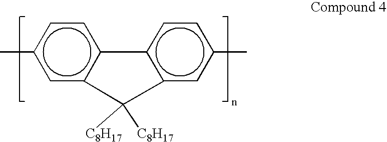

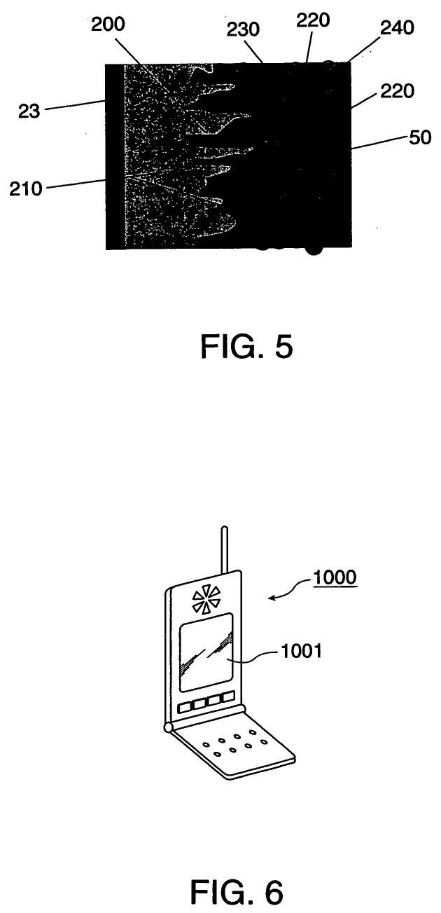

A zirconium oxide particulate film is used for an upper portion of the light-emitting functional layer (cathode side). The zirconium oxide particulates fulfill their function by itself, and is preferably modified by (covered with) a carbon-fluorine-based silane coupling compound such as CF₃(CF₂)₇(CH₂)₂(CH₃)₂Si(CH₂)₅SiCl₃:F17, CF₃(CF₂)₃(CH₂)₂(CH₃)₂Si(CH₂)₉SiCl₃:F9, or CF₃ (CH₂)₂(CH₃)₂Si(CH₂)₁₂SiCl₃:F3. The modification methods include a method of modifying by vapor and a method of modifying by liquid phase. Either method may be used in the embodiment of the invention, and the layer was modified by vapor. The modified zirconium oxide particulates were dispersed in isopropanol to form a film on the light-emitting functional layer described above. The schematic view is shown in FIG. 5.

Thus, a layered body 500 containing at least the anode (pixel electrode) 23 and light-emitting functional part 60 formed on the base body 100 can be obtained.

(5) As shown in FIG. 4B, the cathode 50 is formed on the light-emitting functional part 60. In the step of forming the cathode 50, a film is formed from an anode material such as aluminum, for example, by a vapor deposition method or a sputtering method. In the case of displaying the full range of colors, the portions of light-emitting functional layer for emitting RGB (red, green, and blue) light should be disposed adjacent to one another, as shown in this figure.

A sealing substrate 30 is then formed in a sealing step in the sealing step, in order to prevent the intrusion of water and oxygen into the inside of the fabricated electroluminescent element, a film 45 with a drying function adheres to the inside of the sealing substrate 30, and further the sealing substrate 30 and substrate 20 are sealed using a sealing resin (not shown). A thermoset resin and an ultraviolet-curable resin are used as sealing resins. The sealing step is preferably performed in the atmosphere of inactive gas such as nitrogen, argon, and helium.

The electroluminescent device 1 fabricated through the steps described above can excellently take out, in particular, light from the side of the pixel electrode 23, for example, by applying a voltage equal to or less than 10 V between both electrodes.

The cathode 50 was formed by a vapor phase process such as a vapor deposition method or a sputtering method in the embodiment described above; instead it may be formed by a liquid phase process with the use of a solution or a dispersion liquid including a conductive material.

That is, for example, the cathode 50 can include a main cathode that has contact with the light-emitting functional part 60 and an auxiliary cathode that is deposited on the main cathode, either the main cathode or the auxiliary cathode being formed from a conductive material. In the embodiment of the invention, it is considered that only the auxiliary cathode fulfils the function because there is the light-emitting functional layer 60. Either the main cathode or the auxiliary cathode as described is formed by a liquid phase process such as a droplet discharging method.

A conductive polymer material made of a polymer compound including ethylenedioxythiophene, for example, is used as a conductive material for forming the main cathode. Specifically, a dispersion liquid of poly(3,4-ethylenedioxythiophene)/poly(styrene sulfonic acid) can be used as the conductive polymer material. As a conductive material for forming the main cathode 50, metallic particulates may be used, and further the metallic particulates may be used together with a conductive polymer, instead of the conductive polymer noted above. In particular, if the main cathode is formed from a mixture material of a conductive polymer and metallic particulates, it becomes possible that the conductivity of the main cathode 50 is surely maintained while the main cathode is baked at a relatively low temperature. Specifically, gold, silver, aluminum, and the like can be used as metallic particulates. Besides metallic particulates such as gold and silver, carbon paste can be adopted.

The auxiliary cathode noted above is deposited on the main cathode so as to improve the conductivity of the entire cathode 50. The auxiliary cathode has a function of protecting the main cathode from oxygen and moisture by covering the main cathode, and can be made from metallic particulates with conductivity. As metallic particulates, conductive materials are not particularly restricted if they are chemically stable; any conductive material, for example, metal and alloys, and specifically aluminum, gold, and silver can be used.

If the cathode 50 can thus be formed by a liquid phase process, the vacuum condition in the vapor phase process becomes unnecessary, and therefore the formation of the cathode 50 subsequent to the formation of the light-emitting functional part 60 is enabled, thereby facilitating the fabrication and improving the productivity. If the pixel electrode (anode) is also formed by a liquid phase process, the whole electroluminescent element including the anode, light-emitting functional layer 60, and cathode can be formed consistently by a liquid phase process thereby to further facilitate the fabrication and further improve the productivity.

The above embodiment has been described taking a bottom emission type electroluminescent device as an example, but this embodiment is not restricted to the device of a bottom emission type, and may be applied to the device of a top emission type, and also to the device of a type of emitting light both to the top and to the bottom.

An example of an electronic apparatus of the above-described embodiment of the invention will be described. The electronic apparatus of the embodiment of the invention contains the electroluminescent device 1 described above as a display section. Specifically, a cellular phone as shown in FIG. 6 is an example of this.

In FIG. 6, reference numeral 1000 denotes the main body of a cellular phone, and reference numeral 1001 denotes the display section using the electroluminescent device 1 of the embodiment of the invention. The cellular phone shown in FIG. 6 contains the display section 1001 including the electroluminescent device of the embodiment of the invention, and therefore is excellent in display characteristics.

The electronic apparatus of the embodiment may be applicable to portable information technology equipment such as a word processor and a personal computer, a watch type electronic apparatus, a flat panel display (such as a television set), and the like other than the cellular phone noted above.

What is claimed is:

1. An electroluminescent device, comprising:
an emissive section, an electron injection and transport section, and a hole injection and transfer section between electrodes;
wherein the electron injection and transport section is made from an inorganic semiconductor material, the hole injection and transfer section from an organic semiconductor material, and the emissive section from a metallic complex.

2. The electroluminescent device according to claim 1, wherein at least one of interfaces between a plurality of the sections is formed by phase separation.

3. The electroluminescent device according to claim 2, wherein the interfaces formed by phase separation are substantially parallel to the electrode.

4. The electroluminescent device according to claim 1, wherein the inorganic semiconductor material is a particulate.

5. The electroluminescent device according to claim 1, wherein the inorganic semiconductor material includes at least two types having different chemical compositions.

6. The electroluminescent device according to claim 1, wherein the inorganic semiconductor material is arranged so that energy of a conductive band is higher as the inorganic semiconductor material is closer to a cathode.

7. The electroluminescent device according to claim 4, wherein at least one type of the particulate of the inorganic semiconductor material is covered with an organic substance having fluoroalkyle.

8. The electroluminescent device according to claim 7, wherein the covered particulate of the inorganic semiconductor material is in contact with a cathode.

9. The electroluminescent device according to claim 4, wherein the particulate includes a plurality of types of inorganic semiconductor materials in one particulate.

10. The electroluminescent device according to claim 1, wherein the inorganic semiconductor material is a metallic oxide.

11. The electroluminescent device according to claim 4, wherein the particulate of the inorganic semiconductor material has a diameter equal to or less than 10 nm.

12. The electroluminescent device according to claim 4, wherein at least one type of the particulate of the inorganic semiconductor material is provided with a metallic complex by a covalent bond.

13. The electroluminescent device according to claim 10, wherein one of the metallic oxides is zirconium oxide.

14. The electroluminescent device according to claim 1, wherein central metal of the metallic complex is iridium.

15. The electroluminescent device according to claim 1, wherein the organic semiconductor material is a hole-transferring polymer.

16. The electroluminescent device according to claim 1, wherein a plurality of the organic semiconductor materials are mixed, each having a phase separation interface.

17. The electroluminescent device according to claim 1, wherein the organic semiconductor material has a triphenylamine skeleton.

18. An electroluminescent device fabrication method for fabricating the electroluminescent device according to claim 1, wherein all layers except for the electrode are formed by a liquid phase process.

19. An electroluminescent device fabrication method for fabricating the electroluminescent device according to claim 1, wherein a phase separation structure is controlled by controlling an atmosphere in a vicinity of a gas-liquid interface when a film is formed.

20. The electroluminescent device fabrication method according to claim 18, wherein a solution having all the particulates of the organic material, the metallic complex, and a metallic compound mixed is used in the liquid phase process.

21. An electronic apparatus comprising:
the electroluminescent device according to claim 1.
